(19) United States
(12) Patent Application Publication
(10) Pub. No.: US 2024/0360554 A1
(43) Pub. Date: Oct. 31, 2024

(54) SOLID SOURCE CHEMICAL VAPORIZER

(71) Applicant: ASM IP Holding B.V., Almere (NL)

(72) Inventors: Davide Proserpio, Zeist (NL); Theodorus G.M. Oosterlaken, Oudewater (NL); Herbert Terhorst, Amersfoort (NL); Didem Ernur, San Diego, CA (US)

(21) Appl. No.: 18/648,094

(22) Filed: Apr. 26, 2024

Related U.S. Application Data
(60) Provisional application No. 63/462,558, filed on Apr. 28, 2023.

(51) Int. Cl. C23C 16/448; C23C 16/08; C23C 16/458; C23C 16/54

(52) U.S. Cl. CPC C23C 16/4481; C23C 16/08; C23C 16/4587; C23C 16/54

(57) ABSTRACT

A solid source chemical vaporizer, an assembly of solid source chemical vaporizers, a substrate processing system comprising the solid source chemical vaporizer or the assembly and a method of forming a layer is disclosed. Embodiments of the presently described solid source chemical vaporizer comprise a vessel, a gas inlet, a gas outlet and a channel.

### CROSS-REFERENCE TO RELATED APPLICATION(S)

This application claims the benefit of U.S. Provisional Application 63/462,558 filed on Apr. 28, 2023, the entire contents of which are incorporated herein by reference.

### FIELD OF INVENTION

The present disclosure relates to a substrate processing system. More specifically, it relates to a solid source chemical vaporizer for providing a vapor of a solid precursor for the substrate processing system.

### BACKGROUND OF THE DISCLOSURE

Solid precursors are used in chemical reactions for a variety of industries. They are also used in the manufacturing of semiconductor devices for deposition of material layers on substrates.

Some of the solid precursors have a very low vapor pressure at room temperature. Therefore, they have to be heated in order to produce the required amount of reactant vapor to carry out the deposition processes.

Solid precursors are typically held in vessels. These vessels may function as a solid source vaporizer, where the reactant vapor of the solid precursor is created by the provision of heating. Heating results in increasing the vapor pressure of the solid precursor in the vessel. Such solid source vaporizers may have a carrier gas flow system, whereby the carrier gas may flow over the solid precursor to pick up the vapor created as a result of the heating.

The consumption of the solid precursor may affect the properties of the reactant vapor flow exiting the vaporizer. While this may adversely influence the saturation of the carrier gas with the reactant vapor, it may also influence the deposition process characteristics. This may then lead to immature replacement or immature re-filling of the vessel, whereby the remaining solid precursor may thus, be wasted.

Therefore, there may be a need to provide an improved solid source chemical vaporizer.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

It may be an object of the present disclosure to provide a solid source chemical vaporizer for improving solid precursor consumption and for reducing solid precursor waste.

In a first aspect, the present disclosure relates to a solid source chemical vaporizer. This may be suitable for providing a vapor of a solid precursor. The vaporizer may comprise a vessel. The vessel may have walls defining an interior volume and may have a lid for closing the interior volume. The vaporizer may also comprise a gas inlet a gas outlet. It may further comprise a channel that may be constructed and arranged to hold the solid precursor within the interior volume. The channel may extend between the gas inlet and the gas outlet, thereby defining a flow path from the gas inlet to the gas outlet. The channel may be constructed with a cross sectional area perpendicular to the flow path that may be reduced along the flow path of the channel from the gas inlet to the gas outlet.

The solid source chemical vaporizer according to embodiments of the first aspect of the present disclosure may allow for optimizing solid precursor usage. This may then help to reduce solid precursor waste.

It may be an advantage that the solid source chemical vaporizer may allow for optimized delivery of vapor of solid precursors that have lower vapor pressures at room temperature.

It may be an advantage that an adequate saturation of the carrier gas with the vapor of the solid precursor may be obtained.

It may further be an advantage that the flow exiting the solid source chemical vaporizer may provide a carrier gas saturated with the vapor of the solid precursor for an extended period of time. This may advantageously allow for processing an increased number of substrates.

It may further be an advantage that it may be provided an efficient utilization of solid precursors particularly having a lower vapor pressure, thereby also reducing manufacturing costs of semiconductor devices.

In a second aspect, the present disclosure relates to an assembly of solid source chemical vaporizers. The assembly may be suitable for providing a vapor of a solid precursor. The assembly may comprise a plurality of solid source chemical vaporizers connected to one another. Each of the plurality of solid source chemical vaporizers may comprise a vessel, The vessel may have walls defining an interior volume and may have a lid for closing the interior volume. Each of the plurality of solid source chemical vaporizers may also comprise a gas inlet, a gas outlet and a channel. The channel may be constructed and arranged to hold the solid precursor within the interior volume. The channel may extend between the gas inlet and the gas outlet, thereby defining a flow path from the gas inlet to the gas outlet. The channel may be constructed with a cross sectional area perpendicular to the flow path that may be substantially constant along the flow path of the channel from the gas inlet to the gas outlet. The substantially constant cross sectional area of the channel of each of the plurality of solid source chemical vaporizers may be different from one another.

The solid source chemical vaporizer according to embodiments of the second aspect of the present disclosure may also allow for optimizing solid precursor usage. This may then help to reduce solid precursor waste.

It may advantageously enable the provision of an optimized amount of solid precursor in the vessel, whereby use of the provided amount may be improved. This may then also allow for minimizing precursor waste.

In a third aspect the present disclosure relates to a substrate processing system. The substrate processing system may comprise a substrate processing apparatus. The substrate processing apparatus may comprise a process chamber constructed and arranged to receive at least one substrate. The substrate processing apparatus may further comprise a solid source chemical vaporizer according to embodiments of the first aspect of the present disclosure. The solid source chemical vaporizer may be operably connected to the substrate processing apparatus. Alternatively, the substrate processing apparatus may further comprise an assembly of solid source chemical vaporizers according to embodiments of the second aspect of the present disclosure. The assembly may be operably connected to the substrate processing apparatus.

The substrate processing system may be advantageous in providing an optimized use of solid precursor chemical, whereby its waste may thus, be reduced. Such a system may further reduce overall manufacturing cost as solid precursor waste may be minimized.

In a fourth aspect, the present disclosure relates to a method of forming a layer. The method may comprise providing at least one substrate to a processing chamber. The processing chamber may be comprised in a substrate processing apparatus. The method further comprises providing a vapor of a solid precursor to the process chamber, thereby forming a layer on at least one substrate. The provision of the vapor may comprise providing a solid source chemical vaporizer according to embodiments of the first aspect or an assembly according to the second aspect of the present disclosure. The solid source chemical vaporizer or the assembly may be operably connected to the substrate processing apparatus. Provision of the vapor may further comprise providing thermal energy to the vessel of the solid source chemical vaporizer, thereby forming the vapor of the solid precursor. The vapor of the solid precursor may be guided from the vessel to the substrate processing apparatus.

The method may allow for forming the layer while solid precursor usage may advantageously be optimized. It may also advantageously allow for reducing precursor waste. This may particularly be advantageous when batch processing is used for forming the layer.

It may further be an advantage that the optimized usage of the solid precursor may allow for providing carrier gas flow having adequate saturation with the vapor of the solid precursor delivered to the apparatus for extended period of time with reduced interruption that may be due to precursor re-fill.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure

Like reference numbers will be used for like elements in the drawings unless stated otherwise. Reference signs in the claims shall not be understood as limiting the scope

FIG. 1a: A side view of a channel of a solid source chemical vaporizer according to an embodiment of the first aspect of the present disclosure.

FIG. 1b: A schematic view of channel cross section at two different locations according to an embodiment of the first aspect of the present disclosure.

FIG. 1c: A side view of a channel of a solid source chemical vaporizer according to an embodiment of the first aspect of the present disclosure, with the second bottom surface having sub-surfaces.

FIG. 1d: A tilted top view of a solid source chemical vaporizer, according to an embodiment of the first aspect of the present disclosure, having a vessel with a flat bottom.

FIG. 1e: A tilted top view of a channel of a solid source chemical vaporizer according to an embodiment of the first aspect of the present disclosure.

FIG. 1f: A tilted top view of a solid source chemical vaporizer, according to an embodiment of the first aspect of the present disclosure, having a vessel with a partially inclined bottom.

FIG. 1g: A tilted top view of a channel of a solid source chemical vaporizer according to an embodiment of the first aspect of the present disclosure.

FIG. 2a; FIG. 2b: A schematic of solid source chemical vaporizer having spiral-shaped channels top view according to an embodiment of the first aspect of the present disclosure.

FIG. 3a; FIG. 3b; FIG. 4a; FIG. 4b: A schematic of solid source chemical vaporizer having spiral-shaped channels-cross sectional side view according to an embodiment of the first aspect of the present disclosure.

FIG. 5: A schematic of an assembly of solid source chemical vaporizers-side view according to an embodiment of the second aspect of the present disclosure.

FIG. 6a; FIG. 6b: A schematic of a substrate processing system according to an embodiment of the third aspect of the present disclosure

FIG. 7: A flowchart of an exemplary method according to embodiments of the fourth aspect of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof.

Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail.

Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

Reference throughout the specification to “embodiments” in various places are not necessarily all referring to the same embodiment, but may. Furthermore, the particular features, structures or characteristics maybe combined in any suitable manner, as would be apparent to one of the ordinary skill in the art from the disclosure, in one or more embodiments.

Reference throughout the specification to “some embodiments” means that a particular structure, feature step described in connection with these embodiments is included in some of the embodiments of the present invention. Thus, phrases appearing such as “in some embodiments” in different places throughout the specification are not necessarily referring to the same collection of embodiments, but may.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may.

It is to be noticed that the term “comprising”, as used herein, should not be interpreted as being restricted to the means listed thereafter. It does not exclude other elements or steps. It is thus, to be interpreted as specifying the presence of the stated features, steps or components as referred to. However, it does not prevent one or more other steps, components, or features, or groups thereof from being present or being added.

The terms first, second, third, and the like in the description and in the claims, are used for distinguishing between similar elements. They are not necessarily used for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein.

The following terms are provided only to help in the understanding of the disclosure.

As used herein and unless provided otherwise, the term “flow path” may refer to the path that the carrier gas follows while flowing in the solid source chemical vaporizer.

As used herein and unless provided otherwise, the term “head space” may refer to the available volume within the interior volume of the solid source chemical vaporizer, through which the carrier gas may flow. The head space may be confined to the volume between the lid of the vaporizer and an upper surface of the solid source being held in the channel, the upper surface being the surface of the solid precursor in the vessel before any sublimation of the solid precursor takes place. It is to be noted that consumption of solid precursor occurs that consequently may result in solid precursor that remains in the vaporizer even after partial sublimation of the solid precursor occurs. Therefore, the upper surface of the solid precursor is then at a lower level. The head space may still be referred to the volume between the top surface of the channel (correspondingly the lid of the vaporizer) and the surface of the remaining solid precursor. Consequently, the headspace height (and therefore volume) may have increased due to material consumption.

As used herein and unless provided otherwise, the term “bottom surface” may refer to a surface of the channel on which the solid precursor rests and which is bounded by the walls of the channel.

As used herein and unless provided otherwise, the term “downstream of the flow path” may refer to the portion of the flow path closer to the gas outlet comprised in the solid source chemical vaporizer.

As used herein and unless provided otherwise, the term “upstream of the flow path” may refer to the portion of the flow path closer to the gas inlet comprised in the solid source chemical vaporizer.

As used herein and unless provided otherwise, the term “substantially bowed portion” may refer to portions being curved such that they can connect elongated portions that are parallel to one another and at a certain distance from one another.

As used herein and unless provided otherwise, the term “the first solid source chemical vaporizer in the assembly” may refer to the solid source chemical vaporizer into which the carrier gas enters, where the carrier comes for the first time in contact with the vapor of the solid precursor in the assembly.

As used herein and unless provided otherwise, the term “the last solid source chemical vaporizer in the assembly” may refer to the solid source chemical vaporizer out of which the carrier gas exits the assembly.

As used herein and unless provided otherwise, the term “high surface enhancement structures” may refer to structures that may be designed to be present on a substrate to increase the topography of the surface intentionally.

The disclosure will now be described by a detailed description of several embodiments of the disclosure. It is clear that other embodiments of the disclosure can be configured according to the knowledge of persons skilled in the art in the absence of departure from the technical teaching of the disclosure. The disclosure is limited only by the terms of the claims included herein.

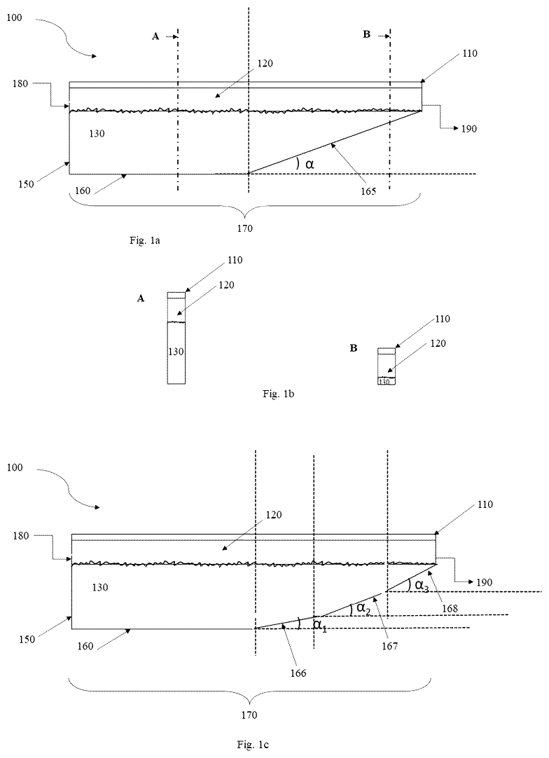

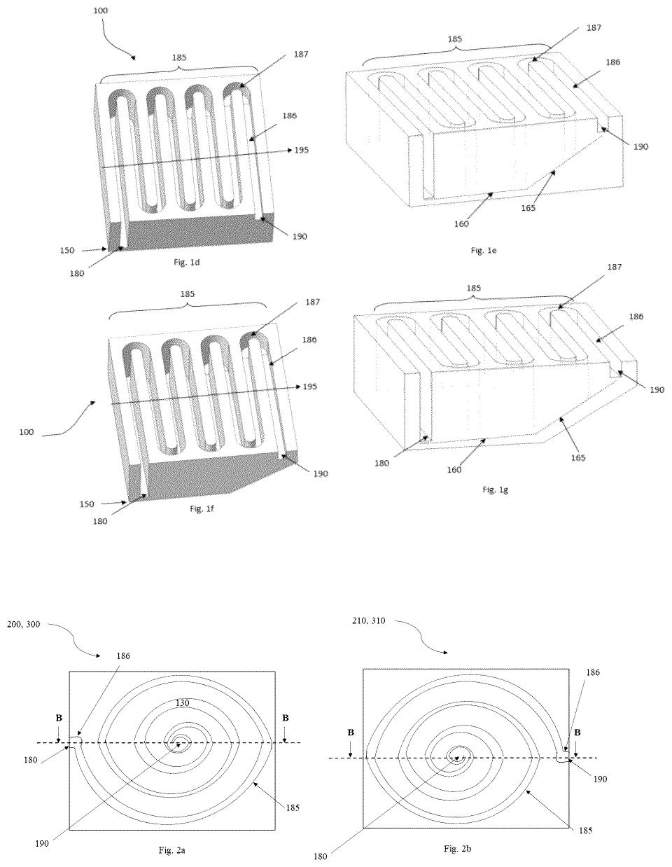

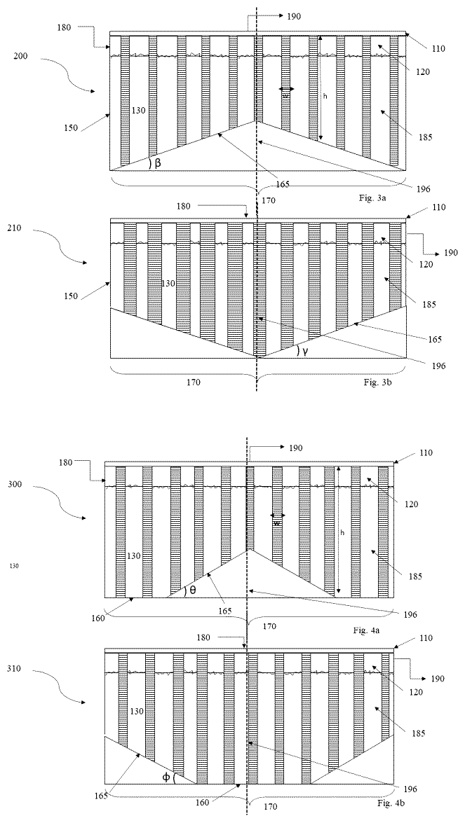

FIG. 1a shows schematic side view of a solid source chemical vaporizer according to an embodiment of the first aspect of the present disclosure. FIG. 1c shows a schematic tilted top view of a solid source chemical vaporizer according to an embodiment of the first aspect of the present disclosure.

The solid source chemical vaporizer (100) may be suitable for providing a vapor of a solid precursor. The vapor of the solid source chemical may be used in a processing chamber for depositing a layer on a substrate. This layer may comprise a metal, a nitride or an oxide. The vaporizer (100) may comprise a vessel (150) having walls defining an interior volume and a lid (110). The lid (110) may be suitable for closing the interior volume. The vaporizer may also comprise a gas inlet (180) and a gas outlet (190).

In some embodiments, at least one of the gas inlet (180) and the gas outlet (190) may be comprised within one of the walls of the vessel (150).

In some embodiments, the gas inlet (180) and the gas outlet (190) may be comprised within the opposing walls of the vessel (150).

In some embodiments, at least one of the gas inlet (180) and the gas outlet (190) may be positioned on the lid (110). This may provide the advantage of reducing the footprint of the solid source vaporizer, thus, leading to an optimized usage of the fab floor space. Furthermore, it may allow for temperature control of the valves, which may be needed before the gas inlet and after the gas outlet, in case the solid source vaporizer may need to be placed in a heated chamber.

The vaporizer (100) may further comprise a channel (185). The channel (185) may be constructed and arranged to hold the solid precursor (130) within the interior volume. The channel may extend between the gas inlet (180) and the gas outlet, thereby defining a flow path from the gas inlet (180) to the gas outlet (190).

A carrier gas may be provided through the gas inlet to the vaporizer (100). The carrier gas may be an inert gas. The carrier gas may be suitable for picking up the vapor of the solid precursor (130) and may further be transferred to outside the vaporizer (100) through the gas outlet (190).

A head space (120) may be present within the interior volume allowing for the flow of the carrier gas and thereby facilitating the pick-up of the vapor of the solid precursor by the carrier gas along the flow path.

In embodiments, the solid source chemical vaporizer (100) may further comprise heating elements (not shown in the figures) for providing thermal energy to the vessel (150). The heating elements may heat the vessel (150) to a temperature that is enough to vaporize the solid precursor (130). In embodiments, the heating elements may provide electrical heating to the vessel (150) such as for example by the use of resistance heaters.

FIG. 1b shows a schematic view of channel cross section at two different locations along the flow path obtained through dotted line A and B as shown in FIG. 1a. The channel (185) may be constructed with a cross sectional area that may be perpendicular to the flow path. The cross sectional area may be reduced along the flow path of the channel (185) from the gas inlet (185) to the gas outlet (190). The cross section may be reduced while the head space (120) is kept substantially constant along the flow path.

As the carrier gas enters in the vessel (150) through the gas inlet (180) and travels through the head space (120) along the flow path, it may get saturated with the vapor of the solid precursor, whereby creation of the vapor results in solid precursor consumption. However, saturation of the carrier gas early on in the flow path may lead to a decrease in the consumption of the solid precursor (130) along the flow path, particularly in the neighborhood of the gas outlet (190). The uneven consumption of the solid precursor may affect the properties of the gas flow at the gas outlet (190) and may lead to, such as for example, not only inadequate saturation of the carrier but also increased amount of left-over solid precursor in the channel. This may then lead to an early replacement or early re-fill of the solid precursor vessel.

Therefore, the reducing cross section along the flow path, while keeping the head space constant, may result in a decreasing volume of solid precursor held in the channel along the flow path. This may then provide the advantage of a balanced saturation of the carrier gas and a balanced solid source consumption and thus, minimizing solid precursor waste. This may further help to provide the properties of the gas flow at the gas outlet (190) to remain substantially constant, such as the flow rate of the gas and concentration of the solid precursor vapor in the gas.

In embodiments, the channel (185) of the solid source chemical vaporizer (100) may comprise a bottom surface (170). The bottom surface (170) may have a surface profile that may be designed to reduce the height of the channel so that a decreasing amount of solid precursor (130) may be held in the channel (185) near the gas outlet (190). The decreasing amount of solid precursor (130) held in the channel (185) may allow for minimizing precursor waste due to the expected decrease in precursor consumption throughout the flow path, thereby, compensating for the saturation of the carrier gas towards the gas outlet (190), particularly during the use of the solid precursor in the channel. The head space (120) being kept substantially constant along the flow path, may thus be compensated by reducing the height of the channel (185), which may be achieved by designing the surface profile of the bottom surface (170).

In some embodiments, the channel (185) may be integrally formed within the vessel (150). This may thus, infer that the bottom surface (170) of the channel may be comprised in the bottom surface of the vessel (150).

In some embodiments, the channel (185) may be integrally formed within a tray (not shown in the figures) and the tray may be receivable in the interior volume of the vessel (150). This may thus, infer that the bottom surface (170) of the channel may at least partially be comprised in the bottom surface of the tray. This may be allowed for easier cleaning of the tray, easier precursor re-fill and reduced downtime of the vaporizer due to maintenance.

In embodiments, the bottom surface (170) of the channel (185) may be at least partially inclined to reduce the height of the channel along the flow path. This may allow for providing a decreasing amount of solid precursor held in the channel (185) near the gas outlet (190).

Thus, in some embodiments, the bottom surface may thus, comprise a first bottom surface (160) and a second bottom surface (165). In order to compensate for the substantially constant head space (120) and the reducing height of the channel (185) along the flow path, the second bottom surface (165) may be inclined with respect to the first bottom surface (160).

In some embodiments, the second bottom surface (165) may be comprised within at least 25% of the bottom surface (170).

In some embodiments, the second bottom surface (165) may be comprised within at least 10% of the bottom surface (170).

This may depend on channel dimensions, process parameters such as for example, flow rate, pressure. Without wishing to be bound by theory, it can be noted that in order to have a channel with a capacity to hold a higher amount of the solid precursor and thus, may last for many process runs, then it may be advantageous that the second bottom surface (165) may be comprised within at least 25% of the bottom surface (170) or within at least 10% of the bottom surface (170). This may be advantageous in providing a higher reduction in solid precursor waste, particularly, in comparison to a channel having a substantially constant channel height.

In some embodiments, the bottom surface (170) of the channel (185) may be substantially fully inclined along the flow path. In other words, the bottom surface (170) may consist only of an inclined bottom surface (165) along the flow path.

In some embodiments, the substantially fully inclined bottom surface of the channel may have a slope that may be substantially constant along the flow path (not shown in the figures). This may then allow for a substantial gradual reduction in the height of the channel along the flow path.

In embodiments, the second bottom surface (165) may be at a downstream of the flow path. In other words, it may be that the height of the channel is reduced downstream of the flow path towards the gas outlet (190). This may be advantageous in providing a reducing amount of solid precursor (130) held in the channel (185) since the head space is kept substantially constant along the flow path. The fact that the carrier gas gets saturated with the vapor of the solid precursor (130) along the flow path may thus, result in a decrease in the vapor uptake by the carrier gas towards the gas outlet (190). Therefore, by keeping a decreased amount of solid precursor (130) in the channel, particularly towards the gas outlet (190) thanks to the inclined bottom surface (165), solid precursor waste may advantageously be minimized in comparison of a vessel absent of the inclined second bottom surface downstream of the flow path.

In some embodiments, the decrease in the channel height over the second bottom surface (165), which is at the downstream of the flow path, may be a gradual decrease as schematically shown in FIG. 1a. In other words, the decrease in channel height over the second bottom surface (165) may follow a linear decrease that may be depicted by the angle of inclination (a), where the first bottom surface (160) transforms into the second bottom surface (165). Thus, the angle of inclination (a) may be the angle between the first bottom surface (160) and the second bottom surface (165).

In some embodiments, the decrease in the channel height over the second bottom surface (165), which is at the downstream of the flow path, may be a step-wise decrease, wherein each step may have its own gradual decrease as schematically shown in FIG. 1c. In other words, the decrease in channel height over the second bottom surface (165) may follow a step-function, wherein each step may be depicted by a different angle of inclination (α₁, α₂, α₃). This may, in other words, infer that the second bottom surface (165) may consist of several sub-surfaces (166, 167, 168), each having a different angle of inclination (α₁, α₂, α₃) with respect to the first bottom surface (160). The step-wise decrease in the channel height may also allow for reducing solid precursor waste. It may also allow tailoring the solid precursor consumption and thus, reducing the waste that may also be tailored for a specific process.

In embodiments, α₃ may be larger than α₂, which may be larger than α₁, such as α₃>α₂>α₁.

In some embodiments, α₃ may be smaller than α₂, which may be smaller than α₁, such as α₂<α₂<α₁.

In embodiments, the length of each sub-surface (166, 167, 168) and the inclination angle of each of the sub-surfaces with respect to the first bottom surface (160) may be adjusted mutually dependent or independent from one another to allow for optimized precursor placement in the vessel (150). This may advantageously provide for an optimized solid precursor (130) usage, thereby minimizing its waste.

FIG. 1d is a schematic representation of a tilted top view of a solid source chemical vaporizer, according to an embodiment of the first aspect of the present disclosure, where the vessel may have a flat bottom and FIG. 1e is a schematic representation of a tilted top view of a channel of a solid source chemical vaporizer shown in FIG. 1d.

The second bottom surface (165) of the channel may be at a downstream of the flow path as it is located in the neighborhood of the gas outlet (190) and it may be inclined with respect to the first bottom surface (160). The angle of inclination (a) with respect to the first bottom surface (160) may be lower than 90 degrees.

FIG. 1f is a schematic representation of a tilted top view of a solid source chemical vaporizer, according to an embodiment of the first aspect of the present disclosure, where the vessel may have an inclined bottom and FIG. 1g is a schematic representation of a tilted top view of a channel of a solid source chemical vaporizer shown in FIG. 1f.

The second bottom surface (165) of the channel may be at a downstream of the flow path as it is located in the neighborhood of the gas outlet (190) and the second bottom surface (165) may follow the inclined portion of the bottom of the vessel (150). The second bottom surface (165) may be inclined with respect to the first bottom surface (160) of the channel. The first bottom surface (160) of the channel may be aligned with the flat portion of the bottom of the vessel (150).

In some embodiments, the angle of inclination (a) may be lower than 60 degrees. In some embodiments, the angle of inclination (a) may be lower than 10 degrees.

In embodiments, the channel (185) may comprise a plurality of channels. The plurality of channels may comprise a plurality of elongated portions (186) and a plurality of substantially bowed portions (187).

In an embodiment, each of the plurality of elongated portions (186) may be connected to each of the plurality of substantially bowed portions (187). The channel (185) may then have a serpentine-shape, thus, forming a serpentine-shaped flow path (FIG. 1d). In other words, this may form a meander-shaped channel, thus, forming a meander-shaped flow path from the gas inlet (180) to the gas outlet (190). This may provide the advantage of loading the vessel (150) with an increased amount of solid precursor (130) within a given interior volume of the vessel (150). In other words, a higher amount of solid precursor may be held in the vaporizer. This may allow for a reduced frequency of the need to refill the vaporizer. Additionally, this may allow for provision of a higher volumetric flow of carrier gas into the vessel, thereby allowing for an increased pick-up of the vapor of the solid precursor by the carrier gas throughout the channel along the flow path. This way, saturation of the carrier gas with the vapor of the solid source may be easily achieved and maintained after substantial consumption of the precursor in the channel.

Furthermore, making the channel longer as disclosed herein, may be an efficient way of increasing the amount of solid precursor that can be held in the channel.

This may be advantageous for some film depositions that may rely on a higher dose of solid precursor vapor to be provided to the process chamber. This may further be advantageous when carrying out the film deposition in a batch processing apparatus, such as for example in a vertical furnace, where a film may be deposited on a plurality of substrates, thereby demanding a higher amount of solid precursor vapor being provided to the process chamber. Furthermore, higher dose may also be needed when processing substrates having high surface enhancement structures. Additionally, a higher precursor flow rate may allow the precursor dose to be delivered in a shorter amount of time and therefore, may allow a shorter process time.

In embodiments, the positioning of the serpentine-shaped channel (185) may be such that the plurality of elongated portions (186) may lie substantially parallel to one another along a first axis (195), along which the first bottom surface (160) transforms into the second bottom surface (165) as schematically shown in FIG. 1c.

In embodiments, the width, length and height of each of the elongated portions of the serpentine-shaped channel may be configured such that an increased amount of solid precursor may be placed in the vessel (150) so as to create an increased total amount of vapor of the solid precursor when thermal energy is provided to the vessel (150). The length of the channel may thus be configured to provide an increased capacity for holding the solid precursor. The width of the channel may be configured such that it enables heat transfer to the solid precursor when thermal energy is provided to the vessel (150). The height of the channel may be configured to allow an initial headspace before any consumption of the solid precursor has taken place.

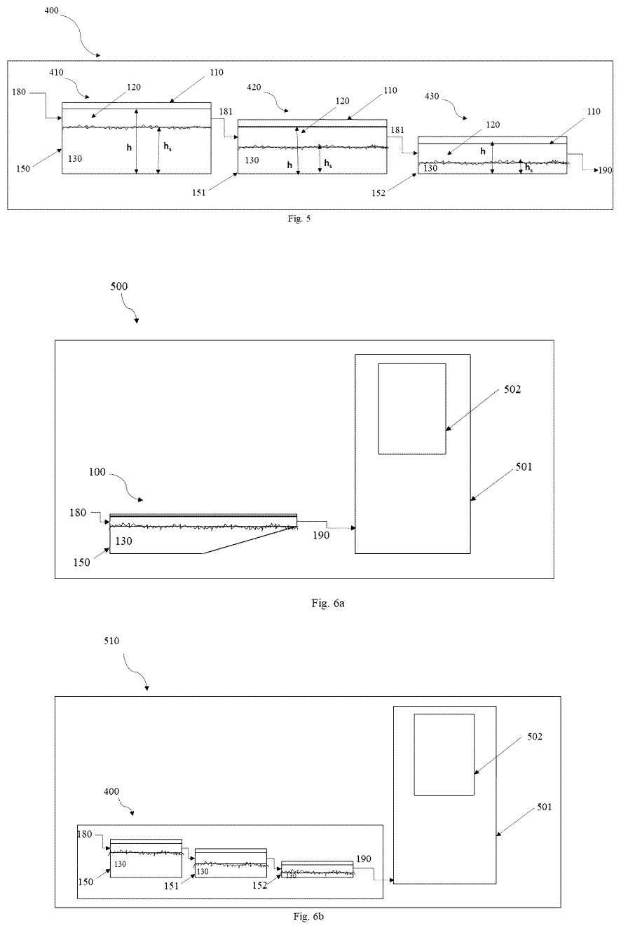

FIG. 2a and FIG. 2b, each show a schematic top-view of a solid source chemical vaporizer having spiral-shaped channels according to an embodiment of the first aspect of the present disclosure.

FIG. 3a and FIG. 3b each show a schematic side-view of solid source chemical vaporizer having spiral-shaped channels according to an embodiment of the first aspect of the present disclosure.

Thus, in an embodiment, each of the plurality of substantially bowed portions (187) may be connected to each other. The channel may then have a spiral-shape, thus forming a spiral-shaped flow path. The spiral-shaped channel may be connected to the gas inlet (180) and to the gas outlet (190) through the elongated portions (186) (FIG. 2a; FIG. 2b).

In some embodiments, the bottom surface (170) of the channel (185) may be substantially fully inclined. In order to accommodate for the reducing height of the channel along the flow path of the spiral-shaped channel, the inclined bottom surface (170) may be configured such that it may extend from the walls of the vessel (150) towards a central axis (196) of the vessel (150).

In some embodiments, as schematically represented in FIG. 3a, the inclined bottom surface may extend from the walls of the vessel (150) towards a central axis (196) of the vessel (150) with a positive slope (B). The inclined surface may comprise at least 2 surfaces that may be converging with each other at the central axis (196) of the vessel (150). The inclination may be defined by an angle of inclination (B), with respect to the bottom of the vessel (150), which may be smaller than 90 degrees.

In some embodiments, the angle of inclination may be (B) lower than 60 degrees.

In an embodiment, from a tilted top view of the vessel (150) (not shown in the figures), the bottom surface (170) may resemble a pyramid, thus, having 4 inclined surfaces, where different inclined surfaces that may merge at the central axis (196) of the vessel (150), make up the inclined bottom surface (165).

In these embodiments, the angle of inclination (B) between the bottom surface of the vessel with each of the different inclined surfaces (165), which make up the bottom surface (170) of the channel (185), may be the same.

In these embodiments, the gas inlet (180) and the gas outlet (190) may be positioned such that the flow path is from the gas inlet (180) to the gas outlet (190) while the channel gradually spirals away from the walls of the vessel (150) towards the central axis (196). This may advantageously allow for reducing solid precursor waste that may be compensated in view of the saturation of the carrier gas with the vapor of the solid precursor along the flow path.

In some embodiments, as schematically represented in FIG. 2a and FIG. 3a, the gas inlet (180) may be comprised within one of the walls of the vessel (150) and the gas outlet (190) may be comprised in the lid (110).

In some embodiments, the gas inlet (180) and the gas outlet (190) may both be comprised in the lid (110) (not shown in the figures).

In some embodiments, as schematically represented in FIG. 3b, the inclined bottom surface may extend from the central axis (196) of the vessel (150) to the walls of the vessel (150) a with a positive slope (y). The inclined surface may comprise at least 2 surfaces that may be converging with each other at the central axis (196) of the vessel (150). The inclination may be defined by an angle of inclination (y), with respect to the bottom of the vessel (150), which may be smaller than 90 degrees.

In some embodiments, the angle of inclination may be (Y) lower than 60 degrees.

In an embodiment, from a tilted top view of the vessel (150) (not shown in the figures), the bottom surface (170) may resemble an inverted hollow pyramid, thus, having 4 inclined surfaces, where different surfaces that may merge at the central axis (196) of the vessel (150) that may make up the inclined bottom surface (165).

In these embodiments, the angle of inclination (Y) between the bottom surface of the vessel with the different inclined surfaces (165), which make up the bottom surface (170) of the channel (185), may be the same.

In these embodiments, the gas inlet (180) and the gas outlet (190) may be positioned such that the flow path is from the gas inlet (180) to the gas outlet (190) while the channel gradually spirals towards the walls of the vessel (150) from the central axis (196). This may advantageously allow for reducing solid precursor waste that may be compensated in view of the saturation of the carrier gas with the vapor of the solid precursor along the flow path.

In embodiments, the angle of inclination (B) (FIG. 3a) may be the same or different from the angle of inclination (Y) (FIG. 3b).

In some embodiments, as schematically represented in FIG. 2b and FIG. 3b, the gas inlet (180) may be comprised in the lid (110) and the gas outlet (190) may be comprised within one of the walls of the vessel (150).

In some embodiments, the gas inlet (180) and the gas outlet (190) may both be comprised in the lid (110) (not shown in the figures).

FIG. 4a and FIG. 4b each show a schematic side-view of solid source chemical vaporizer having spiral-shaped channels according to an embodiment of the first aspect of the present disclosure.

In some embodiments, the bottom surface (170) of the channel (185) may be partially inclined. In other words, the bottom surface (170) may comprise a first bottom surface (160) and a second bottom surface (165) that may be inclined with respect to the first bottom surface (160). The first bottom surface may substantially have a zero inclination with respect to the bottom of the vessel (150).

In some embodiments, as schematically represented in FIG. 4a, the inclined second bottom surface (165) may extend from the first bottom surface (160) towards the central axis (196) of the vessel (150) with a positive slope. The inclination may be defined by an angle of inclination (θ), with respect to the bottom of the vessel (150), which may be smaller than 90 degrees.

In some embodiments, the angle of inclination may be (0) lower than 60 degrees.

The inclined surface may comprise at least 2 surfaces that may be converging with each other at the central axis (195) of the vessel (150)

In an embodiment, from a tilted top view of the vessel (150) (not shown in the figures), the bottom surface (170) may resemble a pyramid, thus, having 4 inclined surfaces, where different inclined surfaces that may merge at the central axis (196) of the vessel (150), that may partially be comprised in the bottom surface (170).

In these embodiments, the angle of inclination (θ) between the bottom surface of the vessel with the different inclined surfaces (165), which make up the bottom surface (170) of the channel (185), may be the same.

In these embodiments, the gas inlet (180) and the gas outlet (190) may be positioned such that the flow path is from the gas inlet (180) to the gas outlet (190) while the channel gradually spirals away from the walls of the vessel (150) as it climbs the second bottom surface (165) coming from the first bottom surface (160) towards the central axis (196). This may advantageously allow for reducing solid precursor waste that may be compensated in view of the saturation of the carrier gas with the vapor of the solid precursor along the flow path.

In some embodiments, as schematically represented in FIG. 2a and FIG. 4a, the gas inlet (180) may be comprised within one of the walls of the vessel (150) and the gas outlet (190) may be comprised in the lid (110).

In some embodiments, the gas inlet (180) and the gas outlet (190) may both be comprised in the lid (110) (not shown in the figures).

In some embodiments, as schematically represented in FIG. 4b, the inclined second bottom surface (165) may extend away from the first bottom surface (165) towards the walls of the vessel (150) with a positive slope. The inclination may be defined by an angle of inclination (Φ), with respect to the bottom of the vessel (150), which may be smaller than 90 degrees.

In some embodiments, the angle of inclination may be (Φ) lower than 60 degrees.

The inclined surface may comprise at least 2 surfaces that may be converging with each other at the central axis (196) of the vessel (150).

In an embodiment, from a tilted top view of the vessel (150) (not shown in the figures), the bottom surface (170) may resemble an inverted hollow pyramid, thus, having 4 inclined surfaces, where the tip is cut-off.

In these embodiments, the angle of inclination (Φ) between the bottom surface of the vessel with the different inclined surfaces (165), which make up the bottom surface (170) of the channel (185), may be the same.

In these embodiments, the gas inlet (180) and the gas outlet (190) may be positioned such that the flow path is from the gas inlet (180) to the gas outlet (190) while the channel gradually spirals towards the walls of the vessel (150) as it climbs to the second bottom surface (165) from the first bottom surface (160). This may advantageously allow for reducing solid precursor waste that may be compensated in view of the saturation of the carrier gas with the vapor of the solid precursor along the flow path.

In some embodiments, as schematically represented in FIG. 2b and FIG. 4b, the gas inlet (180) may be comprised in the lid (110) and the gas outlet (190) may be comprised within one of the walls of the vessel (150).

In some embodiments, the gas inlet (180) and the gas outlet (190) may both be comprised in the lid (110) (not shown in the figures).

In embodiments, the angle of inclination (θ) (FIG. 4a) may be the same or different from the angle of inclination (Φ) (FIG. 4b).

In embodiments, the width (w), length and height (h) of each of the substantially bowed portions of the spiral-shaped channel may be configured such that an increased amount of solid precursor may be placed in the vessel (150) so as to create an increased total amount of vapor of the solid precursor when thermal energy is provided to the vessel (150). The length of each of the substantially bowed portions of the spiral-shaped channel may be configured to provide an increased capacity for holding the solid precursor. The width of each of the substantially bowed portions may be configured such that it enables heat transfer to the solid precursor when thermal energy is provided to the vessel (150). The height of each of the substantially bowed portions may be configured to allow an initial headspace before any consumption of the solid precursor has taken place.

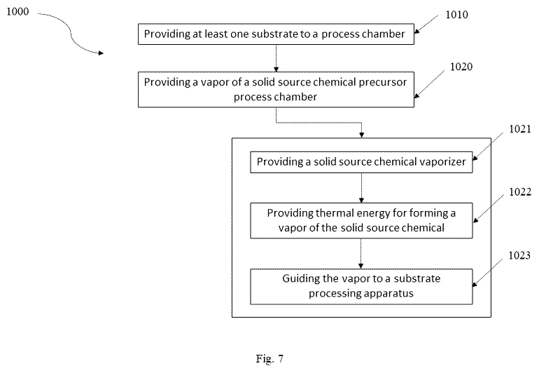

We now return to FIG. 5 showing schematic of a side view of an assembly (400) of solid source chemical vaporizers according to an embodiment of the second aspect of the present disclosure.

The assembly (400) of solid source chemical vaporizers may be suitable for providing a vapor of a solid precursor. The assembly (400) may comprise a plurality of solid source chemical vaporizers (410, 420, 430) connected to one another.

Each one of the plurality of solid source chemical vaporizers (410, 420, 430) may comprise a vessel (150, 151, 152) having walls defining an interior volume. Each vessel may also have a lid (110) that may be suitable for closing the interior volume.

Each one of the plurality of solid source chemical vaporizers (410, 420, 430) may also comprise a gas inlet (180) and a gas outlet (190). In the assembly (400), a gas outlet of a prior solid source chemical vaporizer may become the gas inlet of a latter, consecutive solid source chemical vaporizer. This is shown in FIG. 5 schematically, such that gas outlet of the first solid source chemical vaporizer (181) may become the gas inlet (181) of the second solid source chemical vaporizer. The carrier gas entering into the first solid source chemical vaporizer in the assembly may thus, exit the first solid source chemical vaporizer and may sweep through all the solid source chemical vaporizers in the assembly to pick up the vapor of the solid source chemical created therein.

In embodiments, the routing of the connections between the gas outlets and the gas inlets of solid source chemical vaporizer in the assembly may be changed such as for example, the first solid source chemical vaporizer in the assembly may be connected to another solid source chemical vaporizer not adjacent to it or any one of solid source chemical vaporizers in the assembly may be connected to another solid source chemical vaporizer not adjacent to it. This may provide a continuous operation of the assembly to enable pick up of the vapor of the solid source chemical when such as for example, there is maintenance or precursor re-fill in one of the solid source chemical vaporizers in the assembly.

The channel in each of the solid source chemical vaporizers in the assembly (400) may be constructed and arranged to hold the solid precursor (130) within the interior volume. The channel may extend between the gas inlet and the gas outlet, thereby defining a flow path from the gas inlet to the gas outlet. The channel may be constructed with a cross sectional area perpendicular to the flow that. The cross sectional area may substantially be constant along the flow path of the channel from the gas inlet to the gas outlet. The substantially constant cross sectional area of the channel of each of the plurality of solid source chemical vaporizers may be different from one another.

In some embodiments, for each of the individual solid source chemical vaporizers in the assembly, the cross sectional area may change along the flow path of the channel from the gas inlet to the gas outlet (not shown in the figures). Thus, the bottom surface of the channel in each of the solid source chemical vaporizers may comprise the first bottom surface and the second bottom surface, the second bottom surface being inclined with respect to the first bottom surface.

The difference in the substantially constant cross section of each of the plurality of solid source chemical vaporizers may allow for adjusting the amount of solid precursor contained in each of the plurality of solid source chemical vaporizers. This adjustment may be done in line with the saturation of the carrier gas with the vapor of the solid source chemical along the total flow path, in other words, between the gas inlet (180) going to the first solid source chemical vaporizer and the gas outlet (190) leaving the last solid source chemical vaporizer of the assembly.

The assembly (400) according to embodiments of the second aspect may thus, advantageously allow for optimizing solid precursor usage and reducing solid precursor waste.

The initial head space (120) may be kept at a constant depth for each of the solid source chemical vaporizers comprised in the assembly (400). This may provide the advantage of allowing the carrier gas to pick up the vapor of the solid precursor, at least at the beginning of the flow during which consumption of the solid precursor does not yet modify the surface profile of the solid precursor. By reducing the height (h) of the channel and the height (hs) of the solid precursor (130) for each of the solid source chemical vaporizers along the flow path in the assembly (400), before any sublimation takes place, may help to adjust the head space to the constant depth. Therefore, precursor waste may be decreased as decreasing amount of solid precursor is placed in the vaporizer along the flow path in the assembly (400) since solid precursor consumption may decrease in the flow path when approaching to the gas outlet. This may consequently compensate for the increasing saturation of the carrier gas with the vapor of the solid precursor along the flow path.

Each of the solid source chemical vaporizers comprised in the assembly (400) may further comprise heating elements (not shown in the figures) for providing thermal energy to each of the vessels (150). The heating elements may heat the vessel (150) to a temperature that is enough to vaporize the solid precursor (130). In embodiments, the heating elements may provide electrical heating to the vessel (150) such as for example by the use of resistance heaters.

Each of the solid source chemical vaporizers in the assembly (400) may be kept at a different temperature and at a different pressure from one another. This may advantageously allow for controlling the rate of sublimation, thus, the rate of consumption of the solid precursor contained in each vaporizer.

In embodiments, each of the plurality of solid source chemical vaporizers may be connected in series to one another along the flow path as a function of decreasing cross sectional area. This may thus, provide that a decreasing amount of solid precursor is held in the channel of each of the plurality of solid source chemical vaporizers.

The amount of solid precursor (130) may thus, be distributed among each of the plurality of solid source chemical vaporizers along the flow path in a decreasing manner, so that it may compensate for the decreasing solid source vapor pick up by the carrier gas, which may result from decreasing saturation of the carrier gas with the vapor along the flow path. This may then advantageously allow for optimizing precursor usage and thus, reducing precursor waste.

We now return to FIG. 6a and FIG. 6b showing a schematic of a substrate processing system according to the third aspect of the present disclosure.

The substrate processing system (500, 510) may comprise a substrate processing apparatus (501). The substrate processing apparatus may comprise a process chamber (502). The process chamber may be constructed and arranged to receive at least one substrate.

In some embodiments, the substrate processing apparatus may thus, be a single substrate apparatus.

In some embodiments, the substrate processing apparatus (501) may thus, be a batch substrate apparatus.

In some embodiments, the substrate processing apparatus may be a vertical furnace that may be suitable for processing a plurality of substrates.

The substrate processing system may also comprise a solid source chemical vaporizer (100) according to embodiments of the first aspect of the present disclosure.

In one embodiment, the substrate processing system (500) may comprise the single solid source chemical vaporizer (100) as schematically represented in FIG. 6a. The single solid source chemical vaporizer (100) may be operably connected to the substrate processing apparatus (501). The carrier gas entering the single solid source chemical vaporizer (100) at the gas inlet (180) may leave the single solid source chemical vaporizer (100) at the gas outlet (190) after having picked up the vapor of the solid precursor (130). Carrier gas having the vapor of the solid source chemical may then be delivered to the process chamber (502) of the substrate processing apparatus (501).

In one embodiment, (not shown in the figures), the substrate processing system (500) may comprise the single solid source chemical vaporizer (200, 300, 210, 310). The single solid source chemical vaporizer (100) according to this embodiment, may be operably connected to the substrate processing apparatus (501). The carrier gas entering the single solid source chemical vaporizer (200, 300, 210, 310) at the gas inlet (180) may leave the single solid source chemical vaporizer (200, 300, 210, 310) at the gas outlet (190) after having picked up the vapor of the solid precursor (130). Carrier gas having the vapor of the solid source chemical may then be delivered to the process chamber (502) of the substrate processing apparatus (501).

In one embodiment, (not shown in the figures), the substrate processing system (510) may comprise the assembly (400) of solid source chemical vaporizers according to embodiments of the second aspect of the present disclosure, as schematically represented in FIG. 6b.

The assembly (400) may be operably connected to the substrate processing apparatus (501). The carrier gas entering the assembly (400) at the gas inlet (180) may leave the assembly (400) at the gas outlet (190) having picked up the vapor of the solid precursor (130). Carrier gas having the vapor of the solid source chemical may then be delivered to the process chamber (502) of the substrate processing apparatus (501).

In embodiments, the substrate processing apparatus may be a Chemical Vapor Deposition (CVD) or an Atomic Layer Deposition (ALD) apparatus.

The substrate processing system (500, 510) according to embodiments of the second aspect of the present disclosure may thus, be advantageous in providing an optimized use of solid precursor chemical, whereby its waste may thus, be reduced. Such a system (500, 510) may thus, reduce overall manufacturing cost as solid precursor waste will be minimized.

We now return to FIG. 7 showing a flowchart of an exemplary method according to embodiments of the fourth aspect of the present disclosure.

The method (1000) of forming a layer on a substrate may comprise providing (1010) at least one substrate to a processing chamber. The processing chamber may be comprised in a substrate processing apparatus.

In some embodiments, the substrate processing apparatus may thus, be a single substrate apparatus.

In some embodiments, the substrate processing apparatus (501) may thus, be a batch substrate apparatus that can process a plurality of substrates.

In embodiments, the substrate processing apparatus may be a Chemical Vapor Deposition (CVD) or an Atomic Layer Deposition (ALD) apparatus.

The method (1000) may further comprise providing (1020) a vapor of a solid precursor to the process chamber. This may lead to the formation of the layer on the at least one substrate.

The provision (1020) of the vapor may comprise providing (1021) a solid source chemical vaporizer according to embodiments of the first aspect or the second aspect of the present disclosure. Thus, the solid source chemical vaporizer may be a single solid source chemical vaporizer (100, 200, 210, 300, 310) as schematically represented in FIG. 1, FIG. 2, FIG. 3, FIG. 4 or an assembly (400) of solid source chemical vaporizers as schematically represented in FIG. 5. The solid source chemical vaporizer or the assembly may be operably connected to the substrate processing apparatus.

The provision of the vapor may further comprise providing (1022) thermal energy to the vessel of the solid source chemical vaporizer. Provision of thermal energy forms vapor of the solid precursor.

In embodiments, where an assembly (400) is operably coupled to the substrate processing apparatus, each of the solid source chemical vaporizers may be provided with thermal energy separately. Thermal energy may be provided by using heating elements. The heating elements may heat the vessel (150) to a temperature that is enough to vaporize the solid precursor (130). In embodiments, the heating elements may provide electrical heating to the vessel (150) such as for example by the use of resistance heaters.

The method (1000) may further comprise guiding (1023) the vapor of the solid precursor from the vessel to the substrate processing apparatus.

The method (100) may allow for forming the layer while solid precursor usage may advantageously be optimized and precursor waste may be reduced. This may particularly be advantageous when batch processing is used for forming the layer. Optimized usage of the solid precursor may allow for providing carrier gas flow having adequate saturation with the vapor of the solid precursor delivered to the apparatus for an extended period of time. The extended period may be a result of reduced interruption of precursor delivery that may be due to such as for example, immature precursor re-fill. Full saturation during the whole lifetime of the vessel may be the ideal target for a stable process. If full saturation cannot be obtained, a constant level of (or as high as possible) saturation may be needed for a stable and repeatable process.

In embodiments, the provision (1020) of the vapor may be comprised in a deposition cycle. The deposition cycle may be executed a plurality of times for forming the layer. Thus, the deposition may be executed through an atomic layer deposition process.

In embodiments, the solid precursor may be a transition metal chloride. In embodiments, the solid precursor may be such as for example, HfCl₄, ZrCl₄ or AlCl₃. The solid precursor may thus aid the formation of high-k films, metal oxides or metal nitrides. Thus, field of use for this method may include front end of line such as for example, manufacturing of high-k metal gate transistors, capacitor structures or back end of line such as for example, deposition of liners.

The embodiments of the present disclosure do not limit the scope of invention as these embodiments are defined by the claims appended herein and their legal equivalents. Any equivalent embodiments are intended to be within the scope of this invention. Modifications of the disclosure that are different from one another, in addition to those disclosed herein, may become apparent to those skilled in the art. Such modifications and the embodiments originating therefrom, are also intended to fall within the scope of the claims appended herein.

1. A solid source chemical vaporizer for providing a vapor of a solid precursor, comprising:
a vessel having walls defining an interior volume and a lid for closing the interior volume,
a gas inlet and a gas outlet,
a channel constructed and arranged to hold the solid precursor within the interior volume and extending between the gas inlet and the gas outlet, thereby defining a flow path from the gas inlet to the gas outlet,
wherein the channel is constructed with a cross-sectional area perpendicular to the flow path that is reduced along the flow path of the channel from the gas inlet to the gas outlet.

2. The solid source chemical vaporizer according to claim 1, wherein the channel comprises a bottom surface having a surface profile that is designed to reduce height of the channel so that a decreasing amount of solid precursor is held in the channel near the gas outlet.

3. The solid source chemical vaporizer according to claim 2, wherein the bottom surface comprises a first bottom surface and a second bottom surface, the second bottom surface being inclined with respect to the first bottom surface.

4. The solid source chemical vaporizer according to claim 3, wherein the second bottom surface is at a downstream of the flow path.

5. The solid source chemical vaporizer according to claim 3, wherein the second bottom surface is comprised within at least 25% of the bottom surface.

6. The solid source chemical vaporizer according to claim 5, wherein the second bottom surface is comprised within at least 10% of the bottom surface.

7. The solid source chemical vaporizer according to claim 1, wherein the channel comprises a plurality of channels, wherein the plurality of channels comprises a plurality of elongated portions and a plurality of substantially bowed portions.

8. The solid source chemical vaporizer according to claim 7, wherein each of plurality of elongated portions is connected to each of the plurality of substantially bowed portions, thereby forming a serpentine-shaped flow path.

9. The solid source chemical vaporizer according to claim 7, wherein each of the plurality of substantially bowed portions is connected to each other, thereby forming a spiral-shaped flow path.

10. The solid source chemical vaporizer according to claim 1, further comprising a heating elements for providing thermal energy to the vessel.

11. The solid source chemical vaporizer according to claim 1, wherein the channel is integrally formed within the vessel.

12. The solid source chemical vaporizer according to claim 1, wherein the channel is integrally formed within a tray, the tray being receivable in the interior volume of the vessel.

13. An assembly of solid source chemical vaporizers for providing a vapor of a solid precursor, the assembly comprising a plurality of solid source chemical vaporizers connected to one another, each of the plurality of solid source chemical vaporizers comprising:
a vessel having walls defining an interior volume and a lid for closing the interior volume,
a gas inlet and a gas outlet,
a channel constructed and arranged to hold the solid precursor within the interior volume, and extending between the gas inlet and the gas outlet, thereby defining a flow path from the gas inlet to the gas outlet, wherein the channel is constructed with a cross sectional area perpendicular to the flow path that is substantially constant along the flow path of the channel from the gas inlet to the gas outlet, and
wherein the substantially constant cross sectional area of the channel of each of the plurality of solid source chemical vaporizers is different from one another.

14. The assembly of solid source chemical vaporizers according to claim 13, wherein each of the plurality of solid source chemical vaporizers is connected in series to one another along the flow path as a function of decreasing cross sectional area, so that a decreasing amount of solid precursor is held in the channel of each of the plurality of solid source chemical vaporizers.

15. A substrate processing system, comprising:
a substrate processing apparatus comprising a process chamber constructed and arranged to receive at least one substrate, and
one of:
a solid source chemical vaporizer comprising:
a vessel having walls defining an interior volume and a lid for closing the interior volume,
a gas inlet and a gas outlet,
a channel constructed and arranged to hold the solid precursor within the interior volume and extending between the gas inlet and the gas outlet, thereby defining a flow path from the gas inlet to the gas outlet,
wherein the channel is constructed with a cross-sectional area perpendicular to the flow path that is reduced along the flow path of the channel from the gas inlet to the gas outlet, or
an assembly of solid source chemical vaporizers according to claim 13,
wherein the one of the solid source chemical vaporizer or the assembly being operably connected to the substrate processing apparatus.

16. The substrate processing system according to claim 15, wherein the substrate processing apparatus is a vertical furnace for processing a plurality of substrates.

17. A method of forming a layer on a substrate, comprising:
providing at least one substrate to a processing chamber, the processing chamber being comprised in a substrate processing apparatus,
providing a vapor of a solid precursor to the process chamber, thereby forming a layer on the at least one substrate, wherein the providing of the vapor comprises providing one of:
a solid source chemical vaporizer comprising:
a vessel having walls defining an interior volume and a lid for closing the interior volume,
a gas inlet and a gas outlet,
a channel constructed and arranged to hold the solid precursor within the interior volume and extending between the gas inlet and the gas outlet, thereby defining a flow path from the gas inlet to the gas outlet,
wherein the channel is constructed with a cross-sectional area perpendicular to the flow path that is reduced along the flow path of the channel from the gas inlet to the gas outlet, or
an assembly of solid source chemical vaporizers according to claim 13,
wherein the solid source chemical vaporizer or the assembly being operably connected to a substrate processing apparatus,
providing thermal energy to the vessel of the solid source chemical vaporizer, thereby forming the vapor of the solid precursor, and
guiding the vapor of the solid precursor from the vessel to the substrate processing apparatus.

18. The method according to claim 17, wherein the providing of the vapor is comprised in a deposition cycle and wherein the deposition cycle is executed a plurality of times, thereby forming the layer on the at least one substrate.

19. The method according to claim 17, wherein the solid precursor is a transition metal chloride.
